(19) United States
(12) Patent Application Publication
(10) Pub. No.: US 2025/0194362 A1
(43) Pub. Date: Jun. 12, 2025

(54) DISPLAY DEVICE

(71) Applicant: Samsung Display Co., LTD., Yongin-si (KR)

(72) Inventors: DAEHYUK IM, Yongin-si (KR); HYOYOUNG MUN, Yongin-si (KR)

(21) Appl. No.: 18/904,601

(22) Filed: Oct. 2, 2024

(30) Foreign Application Priority Data
Dec. 7, 2023 (KR) 10-2023-0176740

(51) Int. Cl. H10K 59/131; H05K 1/18

(52) U.S. Cl. CPC H10K 59/131; H05K 1/189; H05K 2201/10128

(57) ABSTRACT

A display device includes: a substrate, a pixel disposed on the substrate, and a first measurement pad disposed on the substrate. The first measurement pad includes: a first electrode disposed on the substrate, a second electrode disposed on the first electrode, and electrically separated from the first electrode, and an insulating layer disposed between the first electrode and the second electrode.

This application claims priority to Korean Patent Application No. 10-2023-0176740, filed on Dec. 7, 2023, and all the benefits accruing therefrom under 35 U.S.C. § 119, the content of which in its entirety is herein incorporated by reference.

### BACKGROUND

The present disclosure herein relates to a display device.

An electronic apparatus, which supplies an image to a user, such as a smartphone, a digital camera, a notebook computer, a navigation system, and a smart television, generally includes a display device for displaying the image. The display device generates the image, and the generated image is supplied to the user through a display screen.

The display device includes a display panel including pixels, and a driver connected to the display panel to drive the pixels. The driver may be mounted on a substrate of the display panel and be connected to the display panel. In addition, the driver may be mounted on a flexible circuit board, and may be connected to the display panel through the flexible circuit board.

The flexible circuit board may be disposed on one side of the display panel and be connected to the display panel. For example, pads disposed on the substrate of the display panel and chip pads disposed under the flexible circuit board may be connected to each other. Conductive balls may be disposed between the pads and the chip pads, and the chip pads may be pressed toward the pads, and the conductive may be compressed. The pads and the chip pads may be connected to each other by the compressed conductive balls.

### SUMMARY

The present disclosure provides a display device in which bonding intervals between pads and chip pads may be more easily measured.

An embodiment of the invention provides a display device including: a substrate, a pixel disposed on the substrate, and a first measurement pad disposed on the substrate, where the first measurement pad includes a first electrode disposed on the substrate, a second electrode disposed on the first electrode, and electrically separated from the first electrode, and an insulating layer disposed between the first electrode and the second electrode.

In an embodiment of the invention, a display device includes: a substrate, a pixel disposed on the substrate, a first measurement pad disposed on the substrate, and a first chip pad disposed on the first measurement pad, where the first measurement pad includes a first electrode disposed on the substrate, and an insulating layer disposed on the first electrode, and the first chip pad is disposed on the insulating layer.

In an embodiment of the invention, a display device includes: a substrate, a plurality of pixels disposed on the substrate, a plurality of pads disposed on the substrate to be connected to the pixels, a first measurement pad not connected to the pixels, and including a first electrode disposed on the substrate, a second electrode disposed on the first electrode, and an insulating layer disposed between the first electrode and the second electrode, an intermediate insulating layer disposed on the second electrode, and a first chip pad disposed on the intermediate insulating layer, wherein the first chip pad is separated from a surrounding conductor to be defined as an island type.

### BRIEF DESCRIPTION OF THE FIGURES

The accompanying drawings are included to provide a further understanding of the invention, and are incorporated in and constitute a part of this specification. The drawings illustrate embodiments of the invention and, together with the description, serve to explain principles of the invention. In the drawings:

FIG. 1 is a perspective view of a display device according to an embodiment of the invention;

FIG. 2 is a diagram exemplarily illustrating a cross-section of a display device illustrated in FIG. 1;

FIG. 3 is a diagram exemplarily illustrating a cross-section of a display panel illustrated in FIG. 2;

FIG. 4 is a plan view of a display panel illustrated in FIG. 2;

FIG. 5 is a diagram illustrating a state in which a display panel, a flexible circuit board, and a printed circuit board illustrated in FIG. 4 are connected;

FIG. 6 is a side view of a display panel in which a display panel illustrated in FIG. 5 is viewed in a second direction;

FIG. 7 is a diagram illustrating a state in which a flexible circuit board illustrated in FIG. 6 is bent;

FIG. 8 is a diagram exemplarily illustrating a cross-section of any one pixel illustrated in FIG. 4;

FIG. 9 is a diagram illustrating a planar configuration of measurement pads illustrated in FIG. 4;

FIG. 10 is a cross-sectional view taken along line I-I′ illustrated in FIG. 4;

FIG. 11 is a cross-sectional view taken along line II-II′ illustrated in FIG. 9;

FIGS. 12 and 13 are diagrams for describing a bonding process of a flexible circuit board illustrated in FIG. 4 and pads illustrated in FIG. 10;

FIGS. 14 and 15 are diagrams illustrating a state of an insulating layer illustrated in FIG. 11 in a bonding process of a pad and a chip pad;

FIG. 16 is a cross-sectional view taken along line III-III′ illustrated in FIG. 9;

FIG. 17 is a cross-sectional view taken along line IV-IV′ illustrated in FIG. 9;

FIG. 18 is a diagram illustrating a state in which first to third measurement pads illustrated in FIG. 9 and first and second measurement terminals disposed on a printed circuit board are connected;

FIG. 19 is a diagram illustrating a state in which a capacitor of a first measurement pad and first and second measurement terminals illustrated in FIG. 18 are connected;

FIG. 20 is a diagram illustrating a configuration of a first measurement pad and a second measurement pad according to another embodiment of the invention;

FIG. 21 is a diagram illustrating a state in which first and second measurement pads illustrated in FIG. 20 and first and second measurement terminals disposed on a printed circuit board are connected;

FIG. 22 is a diagram illustrating a configuration of a first measurement pad and a second measurement pad according to still another embodiment of the invention; and

FIG. 23 is a diagram illustrating a state in which first and second measurement pads illustrated in FIG. 22 and first and second measurement terminals disposed on a printed circuit board are connected.

### DETAILED DESCRIPTION

In this specification, when a component (or region, layer, portion, etc.) is referred to as “on”, “connected”, or “coupled” to another component, it means that it is placed/connected/coupled directly on the other component or a third component can be disposed between them.

The same reference numerals or symbols refer to the same elements. In addition, in the drawings, thicknesses, ratios, and dimensions of components are exaggerated for effective description of technical content.

“At least one” is not to be construed as limiting “a” or “an.” “Or” means “and/or.” Throughout the disclosure, the expression “at least one of a, b or c” indicates only a, only b, only c, both a and b, both a and c, both b and c, all of a, b, and c, or variations thereof. “And/or” includes all combinations of one or more that the associated elements may define.

Terms such as “first” and “second” may be used to describe various components, but the components should not be limited by the terms. These terms are only used for the purpose of distinguishing one component from other components. For example, without departing from the scope of the present invention, a first component may be referred to as a second component, and similarly, a second component may be referred to as a first component. Singular expressions include plural expressions unless the context clearly indicates otherwise.

In addition, terms such as “below”, “lower”, “above”, and “upper” are used to describe the relationship between components shown in the drawings. The terms are relative concepts and are described based on the directions indicated in the drawings.

Unless otherwise defined, all terms (including technical and scientific terms) used in this specification have the same meaning as commonly understood by one of ordinary skill in the art to which this invention belongs. In addition, terms such as terms defined in commonly used dictionaries should be interpreted as having a meaning consistent with the meaning having in the context of the related technology, and should not be interpreted as too ideal or too formal unless explicitly defined here.

Terms such as “include” or “have” are intended to designate the presence of a feature, number, step, action, component, part, or combination thereof described in the specification, and it should be understood that it does not preclude the possibility of presence or addition of one or more other features, numbers, steps, operations, components, parts, or combinations thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within +10%, 5% or 2% of the stated value. Hereinafter, embodiments of the invention will be described with reference to the drawings.

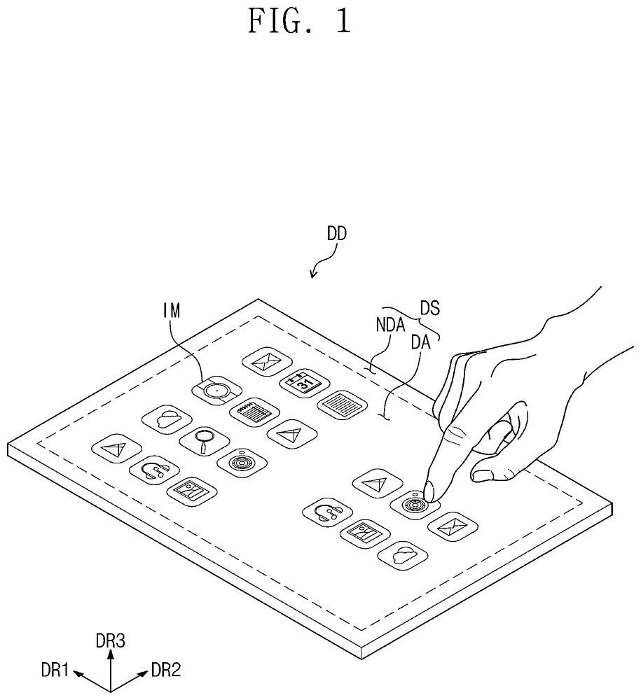

FIG. 1 is a perspective view of a display device according to an embodiment of the invention.

Referring to FIG. 1, a display device DD according to an embodiment of the invention may have a rectangular shape having long sides extending in a first direction DR1 and short sides extending in a second direction DR2 crossing the first direction DR1. However, an embodiment of the invention is not limited thereto, and the display device DD may have various shapes such as a circle or a polygon.

Hereinafter, a direction substantially perpendicular to a plane defined by the first direction DR1 and the second direction DR2 is defined as a third direction DR3. In the present specification, “when seen on a plane” means a state of being seen in the third direction DR3. In other words, “when seen on a plane” means “in a plan view”.

The upper surface of the display device DD may be defined as a display surface DS, and may have a plane defined by the first direction DR1 and the second direction DR2. Images IM generated in the display device DD may be supplied to a user through the display surface DS.

The display surface DS may include a display region DA and a non-display region NDA around the display region DA. The display region DA may display an image, and the non-display region NDA may not display the image. The non-display region NDA may surround the display region DA, and may define an exterior of the display device DD printed in a predetermined color.

The display device DD may be used in large-sized electronic apparatuses such as televisions, monitors, or billboards. In addition, the display device DD may be used in small- and medium-sized electronic apparatuses such as personal computers, notebook computers, private digital terminals, car navigation systems, game consoles, smartphones, tablet computers, or cameras. However, these are just supplied as exemplary embodiments, and may be also used to other electronic apparatuses without departing from the concept of the invention.

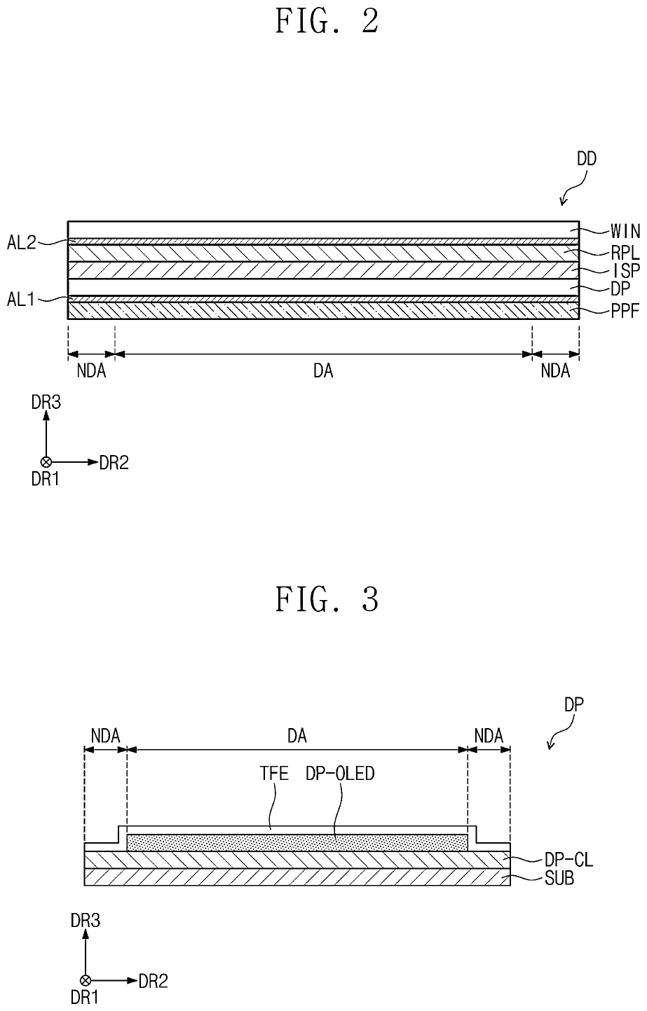

FIG. 2 is a diagram exemplarily illustrating a cross-section of the display device illustrated in FIG. 1.

FIG. 2 exemplarily illustrates a cross-section of a display device DD seen in the first direction DR1.

Referring to FIG. 2, the display device DD may include a display panel DP, an input-sensing portion ISP, an anti-reflective layer RPL, a window WIN, a panel-protecting film PPF, and first and second adhesive layers AL1 and AL2.

The display panel DP may be a flexible display panel. The display panel DP according to an embodiment of the invention may be a light-emitting display panel. For example, the display panel DP may be an organic light-emitting display panel, or an inorganic light-emitting display panel. A light-emitting layer of the organic light-emitting display panel may include an organic light-emitting material. A light-emitting layer of the inorganic light-emitting display panel may include a quantum dot and a quantum rod. Hereinafter, the display panel DP will be described as the organic light-emitting display panel.

The input-sensing portion ISP may be disposed on the display panel DP. The input-sensing portion ISP may include a plurality of sensing portions (not shown) for sensing an external input in a capacitive manner. When the display device DD is manufactured, the input-sensing portion ISP may be directly manufactured on the display panel DP. However, an embodiment of the invention is not limited thereto, and the input-sensing portion ISP may be manufactured as a panel separated from the display panel DP, and then may be attached to the display panel DP by an adhesive layer in another embodiment.

The anti-reflective layer RPL may be disposed on the input-sensing portion ISP. When the display device DD is manufactured, the anti-reflective layer RPL may be directly manufactured on the input-sensing portion ISP. However, an embodiment of the invention is not limited thereto, and the anti-reflective layer RPL may be manufactured separated from the display panel DP, and then may be attached to the input-sensing portion ISP by an adhesive layer in another embodiment.

The anti-reflective layer RPL may be defined as an anti-reflective film of external light. The anti-reflective layer RPL may reduce reflectance of the external light incident from the top of the display device DD toward the display panel DP. The external light may not be viewed to a user by the anti-reflective layer RPL.

When the external light propagating toward the display panel DP reflects on the display panel DP and is supplied to an external user again, the display panel DP may serve as a mirror, and the user may view the external light. In order to prevent such a phenomenon, the anti-reflective layer RPL may exemplarily include a plurality of color filters that display the same color as pixels of the display panel DP.

The color filters may filter the external light to the same color as the pixels. In this case, the external light may not be viewed to the user. However, an embodiment of the invention is not limited thereto, and the anti-reflective layer RPL may include a retarder and/or a polarizer so as to reduce the reflectance of the external light in another embodiment.

The window WIN may be disposed on the anti-reflective layer RPL. The window WIN may protect the display panel DP, the input-sensing portion ISP, and the anti-reflective layer RPL from an external scratch and impact.

The panel-protecting film PPF may be disposed under the display panel DP. The panel-protecting film PPF may protect the lower portion of the display panel DP. The panel-protecting film PPF may include a flexible plastic material such as polyethylene terephthalate (“PET”).

The first adhesive layer AL1 may be disposed between the display panel DP and the panel-protecting film PPF, and the display panel DP and the panel-protecting film PPF may be attached to each other by the first adhesive layer AL1. The second adhesive layer AL2 may be disposed between the window WIN and the anti-reflective layer RPL, and the window WIN and the anti-reflective layer RPL may be attached to each other by the second adhesive layer AL2.

FIG. 3 is a diagram exemplarily illustrating a cross-section of the display panel illustrated in FIG. 2.

FIG. 3 exemplarily illustrates a cross-section of a display panel DP seen in the first direction DR1.

Referring to FIG. 3, the display panel DP may include a substrate SUB, a circuit element layer DP-CL disposed on the substrate SUB, a display element layer DP-OLED disposed on the circuit element layer DP-CL, and a thin-film encapsulation layer TFE disposed on the display element layer DP-OLED.

The substrate SUB may include a display region DA and a non-display region NDA around the display region DA. The substrate SUB may include glass or a flexible plastic material such as polyimide (“PI”). The display element layer DP-OLED may be disposed on the display region DA.

A plurality of pixels may be disposed in the circuit element layer DP-CL and the display element layer DP-OLED. Each of the pixels may include a transistor disposed in the circuit element layer DP-CL, and a light-emitting element which is disposed in the display element layer DP-OLED and connected to the transistor.

The thin-film encapsulation layer TFE may be disposed on the circuit element layer DP-CL so as to cover the display element layer DP-OLED. The thin-film encapsulation layer TFE may protect the pixels from moisture, oxygen, and external foreign matters.

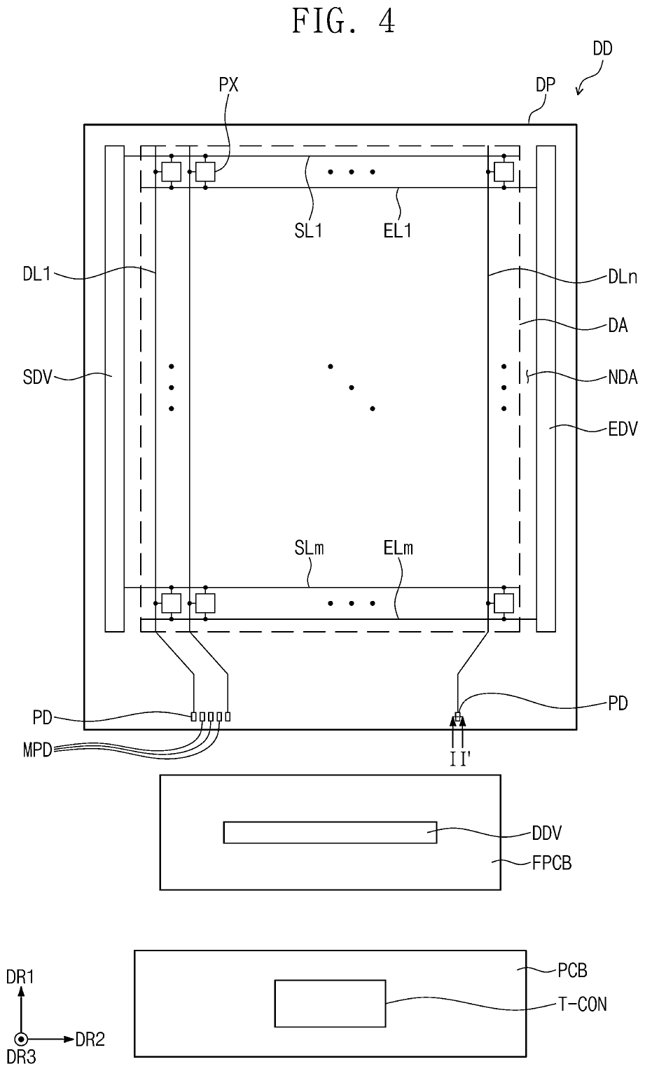

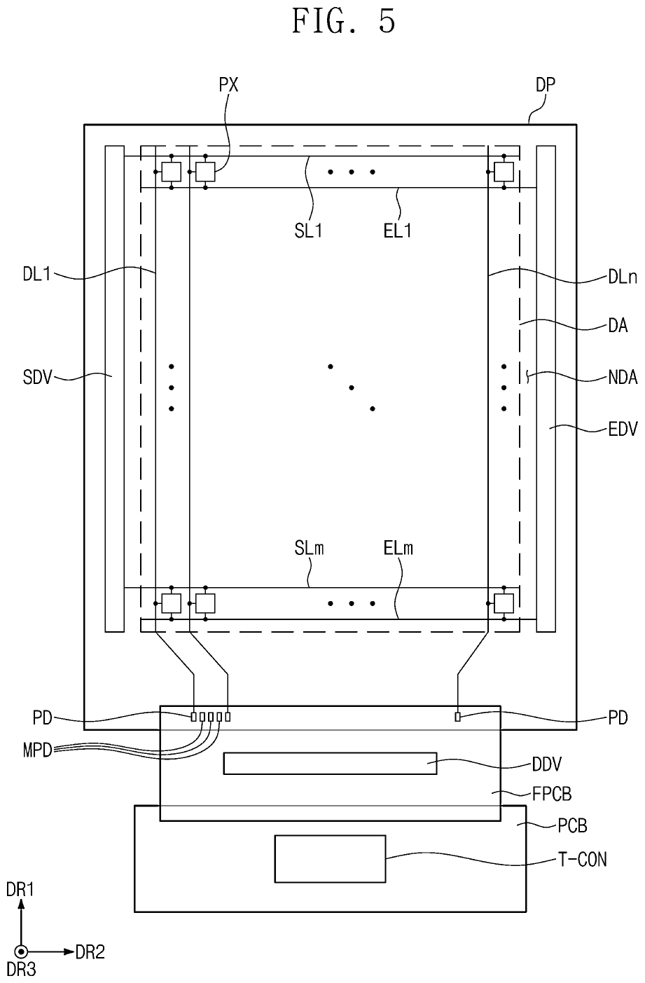

FIG. 4 is a plan view of the display panel illustrated in FIG. 2. FIG. 5 is a diagram illustrating a state in which the display panel, the flexible circuit board, and the printed circuit board illustrated in FIG. 4 are connected. As used herein, the “plan view” is a view in a thickness direction (i.e., DR3) of the substrate SUB.

Referring to FIGS. 4 and 5, a display device DD may include a display panel DP, a scan driver SDV, a data driver DDV, a light emission driver EDV, a plurality of pads PD, a timing controller T-CON, a flexible circuit board FPCB, and a printed circuit board PCB.

The display panel DP may have a rectangular shape having long sides extending in the first direction DR1, and short sides extending in the second direction DR2, but a shape of the display panel DP is not limited thereto. The display panel DP may include a display region DA and a non-display region NDA surrounding the display region DA.

The display panel DP may include a plurality of pixels PX, a plurality of scanning lines SL1 to SLm, a plurality of data lines DL1 to DLn, and a plurality of light-emitting lines EL1 to ELm. The pixels PX may be disposed in the display region DA. The scan driver SDV and the light emission driver EDV may be disposed in the non-display region NDA adjacent to the long sides of the display panel DP, respectively.

The data driver DDV may be disposed on the flexible circuit board FPCB. The flexible circuit board FPCB may be connected to the non-display region NDA adjacent to any one short side of the short sides of the display panel DP. When seen on a plane, the flexible circuit board FPCB may be connected to the lower end of the display panel DP. The data driver DDV may be connected to the display panel DP through the flexible circuit board FPCB. However, an embodiment of the invention is not limited thereto, and the data driver DDV may be directly disposed on the non-display region NDA in another embodiment.

The scanning lines SL1 to SLm may extend in the second direction DR2 and be connected to the pixels PX and the scan driver SDV. The data lines DL1 to DLn may extend in the first direction DR1 and be connected to the pixels PX. The light-emitting lines EL1 to ELm may extend in the second direction DR2 and be connected to the pixels PX and the light emission driver EDV.

The pads PD may be disposed on the display panel DP. The pads PD may be adjacent to the lower end of the display panel DP. The pads PD may be arranged in the second direction DR2. The data lines DL1 to DLn may be connected to the pads PD. The pads PD may be connected to the pixels PX through the data lines DL1 to DLn.

The measurement pads MPD may be disposed between two arbitrary pads PD adjacent to each other. The measurement pads MPD are exemplarily disposed on the left side of the display panel DP in the lower end of the display panel DP, but positions of the measurement pads MPD are not limited thereto. The measurement pads MPD may be arranged in the second direction DR2. The measurement pads MPD may not be connected to the data lines DL1 to DLn. That is, the measurement pads MPD may not be connected to the pixels PX.

The flexible circuit board FPCB may be connected to the pads PD. The data driver DDV may be connected to the pads PD through the flexible circuit board FPCB. Accordingly, the pads PD connected to the data lines DL1 to DLn may be connected to the data driver DDV through the flexible circuit board FPCB.

Although not shown, the flexible circuit board FPCB may include a plurality of lines connected to the data driver DDV. The lines may be connected to a plurality of chip pads (See CPD in FIG. 12) disposed on the flexible circuit board FPCB. The chip pads may be connected to the pads PD so that the flexible circuit board FPCB and the data driver DDV may be connected to the display panel DP. A connection configuration of the pads PD and the chip pads will be described in detail later.

Although not shown in FIG. 4, first, second, and third chip pads for being connected to the measurement pads MPD may be further disposed on the flexible circuit board FPCB. A connection configuration of the measurement pads MPD and the first, second, and third chip pads will be described in detail later.

The timing controller T-CON may be disposed on the printed circuit board PCB. One side of the flexible circuit board FPCB may be connected to the display panel DP, and the other side of the flexible circuit board FPCB may be connected to the printed circuit board PCB.

The timing controller T-CON may be connected to the data driver DDV through the printed circuit board PCB. In addition, the timing controller T-CON may be connected to the scan driver SDV and the light emission driver EDV through the printed circuit board PCB and the flexible circuit board FPCB. The timing controller T-CON may control operations of the scan driver SDV, the data driver DDV, and the light emission driver EDV.

The scan driver SDV may generate a plurality of scan signals, and the scan signals may be applied to the pixels PX through the scanning lines SL1 to SLm. The data driver DDV may generate a plurality of data voltages, and the data voltages may be applied to the pixels PX through the data lines DL1 to DLn. The light emission driver EDV may generate a plurality of light-emitting signals, and the light-emitting signals may be applied to the pixels PX through the light-emitting lines EL1 to ELm.

The pixels PX may be supplied with the data voltages in response to the scan signals. The pixels PX may display an image by emitting light having luminance corresponding to the data voltages in response to the light-emitting signals. A light-emitting time of the pixels PX may be controlled by the light-emitting signals.

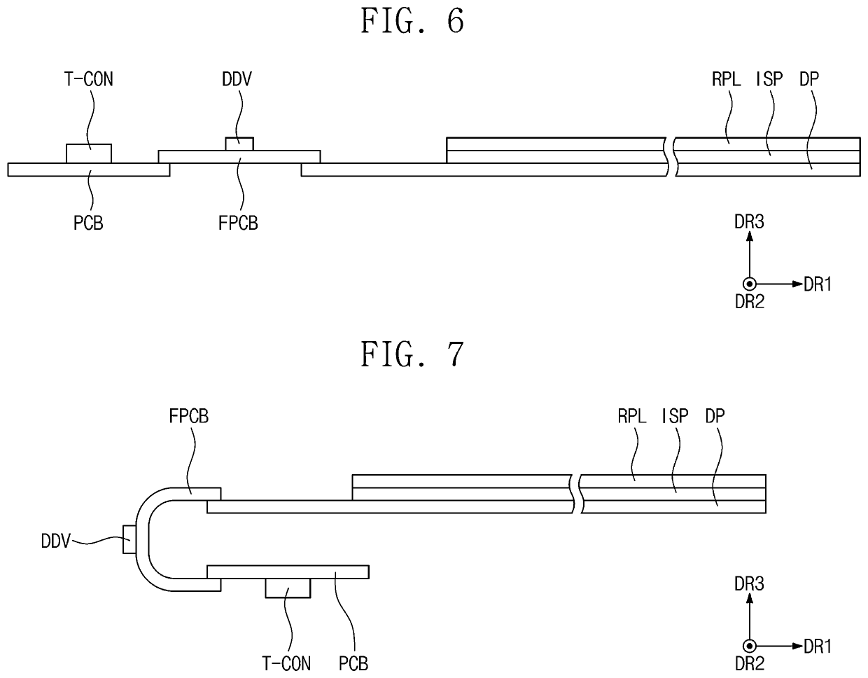

FIG. 6 is a side view, of a display panel, in which the display panel illustrated in FIG. 5 is seen in the second direction. FIG. 7 is a diagram illustrating a state in which the flexible circuit board illustrated in FIG. 6 is bent.

Referring to FIGS. 6 and 7, one side of the flexible circuit board FPCB may be disposed on one side of the display panel DP and be connected to the display panel DP. The other side of the flexible circuit board FPCB may be disposed on one side of the printed circuit board PCB and be connected to the printed circuit board PCB.

A data driver DDV may be disposed on the flexible circuit board FPCB, and the timing controller T-CON may be disposed on the printed circuit board PCB. The data driver DDV may be manufactured in a form of an integrated circuit chip and be mounted on the flexible circuit board FPCB. The timing controller T-CON may be manufactured in a form of an integrated circuit chip and be mounted on the printed circuit board PCB.

The flexible circuit board FPCB may be bent so that the timing controller T-CON and the printed circuit board PCB may be disposed under the display panel DP. Accordingly, when the display panel DP is seen on the display panel DP, the timing controller T-CON and the printed circuit board PCB may not be viewed outside.

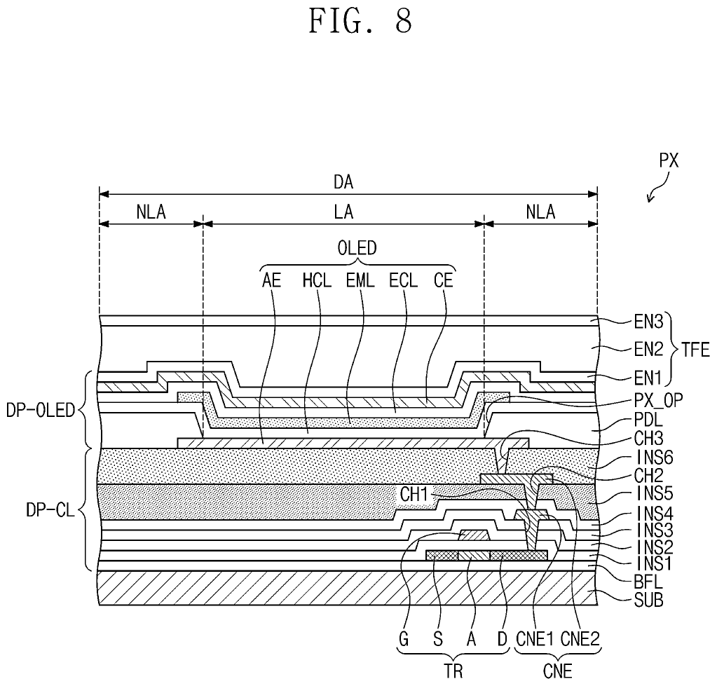

FIG. 8 is a diagram exemplarily illustrating a cross-section of any one pixel illustrated in FIG. 4.

Referring to FIG. 8, a pixel PX may be disposed on a substrate SUB. The pixel PX may include a transistor TR and a light-emitting element OLED. The light-emitting element OLED may include a first electrode AE (or anode), a second electrode CE (or cathode), a hole control layer HCL, an electron control layer ECL, and a light-emitting layer EML.

The transistor TR and the light-emitting element OLED may be disposed on the substrate SUB. One transistor TR is exemplarily illustrated, but the pixel PX may substantially include a plurality of transistors for driving the light-emitting element OLED, and at least one capacitor.

The display region DA may include a light-emitting region LA corresponding to each of the pixels PX and a non-light-emitting region NLA around the light-emitting region LA. The light-emitting element OLED may be disposed on the light-emitting region LA.

A buffer layer BFL may be disposed on the substrate SUB, and the buffer layer BFL may be an inorganic layer. A semiconductor pattern may be disposed on the buffer layer BFL. The semiconductor pattern may include polysilicon, amorphous silicon, or a metal oxide.

The semiconductor pattern may be doped with an N-type dopant or a P-type dopant. The semiconductor pattern may include a highly doped region and a lowly doped region. The highly doped region may have a greater conductivity than the lowly doped region, and may substantially serve as a source electrode and a drain electrode of the transistor TR. The lowly doped region may substantially correspond to an active (or channel) of the transistor TR.

A source region S, a channel region A, and a drain region D of the transistor TR may be formed from the semiconductor pattern. A first insulating layer INS1 may be disposed on the semiconductor pattern. A gate electrode G of the transistor TR may be disposed on the first insulating layer INS1. The gate electrode G may overlap the channel region A in a plan view.

A second insulating layer INS2 may be disposed on the gate electrode G. A third insulating layer INS3 may be disposed on the second insulating layer INS2.

A connection electrode CNE may include a first connection electrode CNE1 and a second connection electrode CNE2 for connecting the transistor TR and the light-emitting element OLED. The first connection electrode CNE1 may be disposed on the third insulating layer INS3, and may be connected to the drain region D through a first contact hole CH1 defined in the first to third insulating layers INS1 to INS3.

A fourth insulating layer INS4 may be disposed on the first connection electrode CNE1. A fifth insulating layer INS5 may be disposed on the fourth insulating layer INS4. The second connection electrode CNE2 may be disposed on the fifth insulating layer INS5. The second connection electrode CNE2 may be connected to the first connection electrode CNE1 through a second contact hole CH2 defined in the fourth and fifth insulating layer INS4 and INS5.

A sixth insulating layer INS6 may be disposed on the second connection electrode CNE2. Layers from the buffer layer BFL to the sixth insulating layer INS6 may be defined as a circuit element layer DP-CL. The first insulating layer INS1 to the sixth insulating layer INS6 may be an inorganic layer or an organic layer.

The first electrode AE may be disposed on the sixth insulating layer INS6. The first electrode AE may be connected to the second connection electrode CNE2 through a third contact hole CH3 defined in the sixth insulating layer INS6. A pixel-defining film PDL in which an opening PX_OP for exposing a predetermined portion of the first electrode AE is defined may be disposed on the first electrode AE and the sixth insulating layer INS6.

The hole control layer HCL may be disposed on the first electrode AE and the pixel-defining film PDL. The hole control layer HCL may include a hole transport layer and a hole injection layer.

The light-emitting layer EML may be disposed on the hole control layer HCL. The light-emitting layer EML may be disposed in a region corresponding to the opening PX_OP. The light-emitting layer EML may include an organic material and/or an inorganic material. The light-emitting layer EML may generate light having any one color of red, green, and blue.

The electron control layer ECL may be disposed on the light-emitting layer EML and the hole control layer HCL. The electron control layer ECL may include an electron transport layer and an electron injection layer. The hole control layer HCL and the electron control layer ECL may be commonly disposed in the light-emitting region LA and the non-light-emitting region NLA.

The second electrode CE may be disposed on the electron control layer ECL. The second electrode CE may be commonly disposed in the pixels PX. A layer on which the light-emitting element OLED is disposed may be defined as the display element layer DP-OLED.

The thin-film encapsulation layer TFE may be disposed on the second electrode CE to cover the pixel PX. The thin-film encapsulation layer TFE may include a first encapsulation layer EN1 disposed on the second electrode CE, a second encapsulation layer EN2 disposed on the first encapsulation layer EN1, and a third encapsulation layer EN3 disposed on the second encapsulation layer EN2.

The first and third encapsulation layers EN1 and EN3 may include an inorganic insulating layer, and may protect the pixel PX from moisture/oxygen. The second encapsulation layer EN2 may include an organic insulating layer, and may protect the pixel PX from foreign matters such as dust particles.

A first voltage may be applied to the first electrode AE through the transistor TR, and a second voltage may be applied to the second electrode CE. When a hole and an electron injected into the light-emitting layer EML are combined to form an exciton, and the exciton transitions to a ground state, the light-emitting element OLED may emit light.

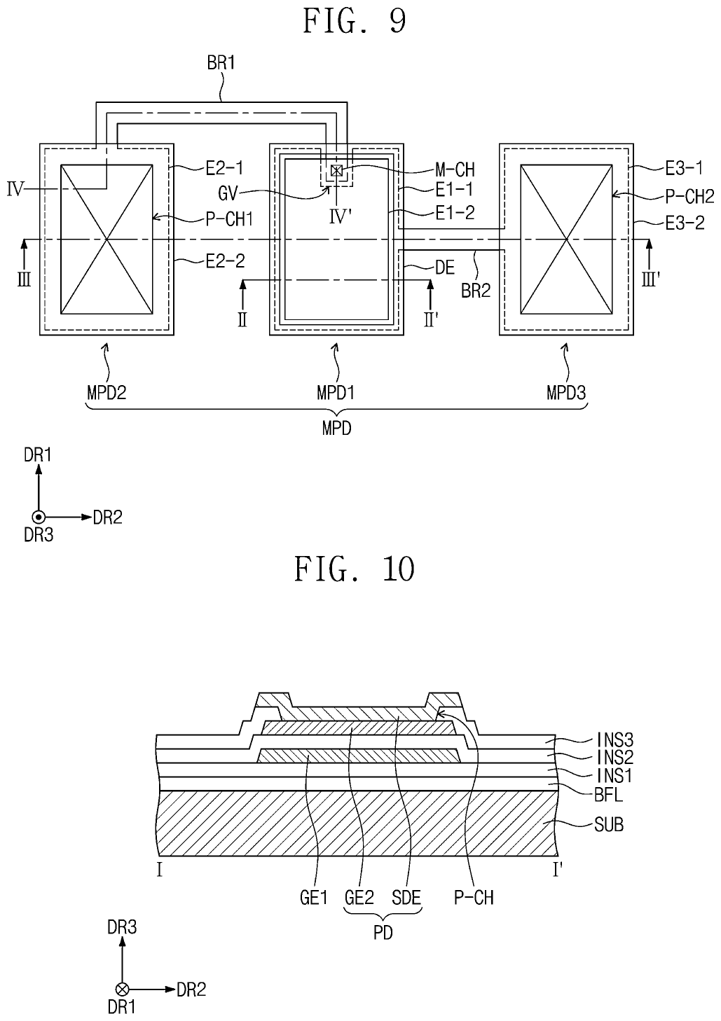

FIG. 9 is a diagram illustrating a planar configuration of the measurement pads illustrated in FIG. 4.

Referring to FIG. 9, measurement pads MPD may each include a first measurement pad MPD1, a second measurement pad MPD2, and a third measurement pad MPD3. The first to third measurement pads MPD1, MPD2, and MPD3 may be arranged in the second direction DR2. The first measurement pad MPD1 may be disposed between the second measurement pad MPD2 and the third measurement pad MPD3.

The first to third measurement pads MPD1, MPD2, and MPD3 may not be connected to the data lines DL1 to DLn. Accordingly, the first to third measurement pads MPD1, MPD2, and MPD3 may not be connected to the pixels PX.

The first measurement pad MPD1 may include a first electrode E1-1 and a second electrode E1-2 disposed on the first electrode E1-1. When seen on a plane, the second electrode E1-2 may overlap the first electrode E1-1. When seen on a plane, the second electrode E1-2 may have a smaller area than the first electrode E1-1.

A dummy electrode DE may be disposed around the second electrode E1-2. When seen on a plane, the dummy electrode DE may surround the second electrode E1-2. The dummy electrode DE may be separated from the second electrode E1-2.

A groove GV may be defined on the first electrode E1-1. When seen on a plane, the groove GV may be defined so as to overlap the second electrode E1-2. Except for a portion in which the groove GV is defined, an exterior of the first electrode E1-1 may overlap the dummy electrode DE in a plan view. A portion, of the first electrode E1-1, covered by the second electrode E1-2 and the dummy electrode DE is exemplarily illustrated as a dotted line.

The second measurement pad MPD2 may include a first electrode E2-1 and a second electrode E2-2 disposed on the first electrode E2-1. When seen on a plane, the first electrode E2-1 may overlap the second electrode E2-2. When seen on a plane, the first electrode E2-1 may have a smaller area than the second electrode E2-2. A portion, of the first electrode E2-1, covered by the second electrode E2-2 is illustrated as a dotted line. The second electrode E2-2 may be connected to the first electrode E2-1 through a first contact hole P-CH1.

The third measurement pad MPD3 may include a first electrode E3-1 and a second electrode E3-2 disposed on the first electrode E3-1. When seen on a plane, the first electrode E3-1 may overlap the second electrode E3-2. When seen on a plane, the first electrode E3-1 may have a smaller area than the second electrode E3-2. A portion, of the first electrode E3-1, covered by the second electrode E3-2 is exemplarily illustrated as a dotted line. The second electrode E3-2 may be connected to the first electrode E3-1 through a second contact hole P-CH2.

The first measurement pad MPD1 may be connected to the second measurement pad MPD2. In addition, the first measurement pad MPD1 may be connected to the third measurement pad MPD3.

Specifically, a first bridge electrode BR1 may be formed by extending from the first electrode E2-1. The first bridge electrode BR1 may extend toward the groove GV. One side of the first bridge electrode BR1 may be disposed in the groove GV, and may overlap the second electrode E1-2, when seen on a plane. In the groove GV, the first bridge electrode BR1 may be connected to the second electrode E1-2 through a contact hole M-CH.

Since the second measurement pad MPD2 is connected to the second electrode E1-2 of the first measurement pad MPD1 through the first bridge electrode BR1, the first measurement pad MPD1 may be connected to the second measurement pad MPD2.

A second bridge electrode BR2 may be formed by extending from the first electrode E1-1 of the first measurement pad MPD1 and the first electrode E3-1 of the third measurement pad MPD3. That is, since the third measurement pad MPD3 is connected to the first electrode E1-1 of the first measurement pad MPD1 through the second bridge electrode BR2, the first measurement pad MPD1 may be connected to the third measurement pad MPD3.

FIG. 10 is a cross-sectional view taken along line I-I′ illustrated in FIG. 4.

Referring to FIG. 10, a first gate electrode GE1 and a pad PD may be disposed on a substrate SUB. The pad PD may be disposed on the first gate electrode GE1. The pad PD may include a second gate electrode GE2 disposed on the first gate electrode GE1, and a source-drain electrode SDE disposed on the second gate electrode GE2.

A buffer layer BFL may be disposed on the substrate SUB, and a first insulating layer INS1 may be disposed on the buffer layer BFL. The first gate electrode GE1 may be disposed on the first insulating layer INS1. A second insulating layer INS2 may be disposed on the first gate electrode GE1 and the first insulating layer INS1.

The second gate electrode GE2 may be disposed on the second insulating layer INS2. A third insulating layer INS3 may be disposed on the second gate electrode GE2 and the second insulating layer INS2. A contact hole P-CH may be defined in the third insulating layer INS3, and the second gate electrode GE2 may be partially exposed by the contact hole P-CH.

The source-drain electrode SDE may be disposed on the third insulating layer INS3. The source-drain electrode SDE may be disposed on the second gate electrode GE2 and be connected to the second gate electrode GE2 through the contact hole P-CH. The pad PD may be formed by the second gate electrode GE2 and the source-drain electrode SDE electrically connected to each other. As described above, the pad PD may be connected to a corresponding pixel PX among the pixels PX.

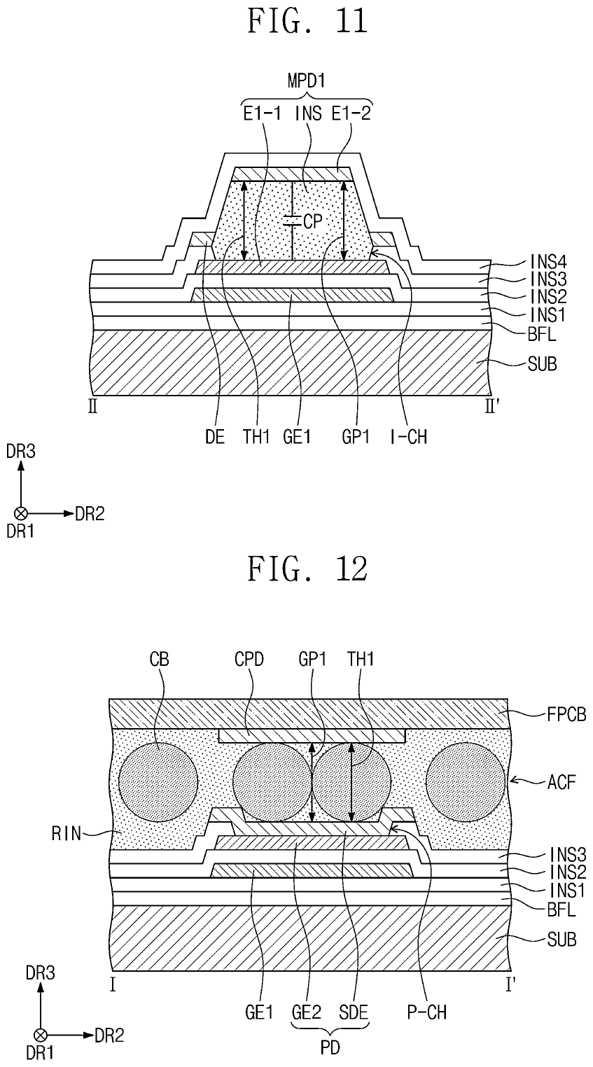

FIG. 11 is a cross-sectional view taken along line II-II′ illustrated in FIG. 9.

Referring to FIG. 11, a first measurement pad MPD1 may be disposed on a substrate SUB. The first measurement pad MPD1 may include a first electrode E1-1, a second electrode E1-2, and an insulating layer INS.

The first electrode E1-1 may be disposed on the substrate SUB, and the second electrode E1-2 may be disposed on the first electrode E1-1. The insulating layer INS may be disposed between the first electrode E1-1 and the second electrode E1-2.

Describing a stack structure more specifically, a buffer layer BFL and a first insulating layer INS1 may be sequentially stacked on the substrate SUB, and a first gate electrode GE1 may be disposed on the first insulating layer INS1. A second insulating layer INS2 may be disposed on the first gate electrode GE1.

The first electrode E1-1 may be disposed on the second insulating layer INS2. The first electrode E1-1 may be disposed on the same layer as a second gate electrode GE2. The first electrode E1-1 may be formed by being simultaneously patterned with the same material as a material of the second gate electrode GE2.

A third insulating layer INS3 may be disposed on the first electrode E1-1 and the second insulating layer INS2. A contact hole I-CH may be defined in the third insulating layer INS3. The first electrode E1-1 may be partially exposed by the contact hole I-CH.

The insulating layer INS may be disposed on the first electrode E1-1 in the contact hole I-CH. The insulating layer INS may include an organic insulating layer INS. For example, the insulating layer INS may include polymer. A thickness of the insulating layer INS in the third direction DR3 may be about 2 micrometers (μm) to about 4 μm. The third direction DR3 may be defined as a direction normal to the upper surface of the substrate SUB.

The second electrode E1-2 may be disposed on the insulating layer INS. The second electrode E1-2 may be disposed on the upper surface of the insulating layer INS. A dummy electrode DE may be disposed on the insulating layer INS adjacent to a side surface of the insulating layer INS.

The second electrode E1-2 and the dummy electrode DE may be formed by being simultaneously patterned with the same material. The dummy electrode DE may be disposed lower than the second electrode E1-2, and as described above, may surround the second electrode E1-2. The second electrode E1-2 and the dummy electrode DE may be formed by being simultaneously patterned with the same material as a material of the source-drain electrode SDE.

The first electrode E1-1 and the second electrode E1-2 may be insulated with each other to be electrically separated. For example, the first electrode E1-1 and the second electrode E1-2 may be electrically separated by the insulating layer INS disposed between the first electrode E1-1 and the second electrode E1-2. The first electrode E1-1 may be electrically separated from the dummy electrode DE.

A fourth insulating layer INS4 may be disposed on the second electrode E1-2, a side surface of the insulating layer INS, the dummy electrode DE, and the third insulating layer INS3. The fourth insulating layer INS4 may be referred to as an “intermediate insulating layer”.

The insulating layer INS may have a first thickness TH1 in the third direction DR3. An interval between the first electrode E1-1 and the second electrode E1-2 may be a first interval GP1. The first interval GP1 may be the same as the first thickness TH1.

A capacitor CP may be formed by the first electrode E1-1 and the second electrode E1-2. A capacitance of the capacitor CP may be about 0.02 picofarads (pF) to about 0.20 pF.

FIGS. 12 and 13 are diagrams for describing a bonding process of the flexible circuit board illustrated in FIG. 4 and the pad illustrated in FIG. 10.

FIGS. 12 and 13 exemplarily illustrate a cross-section corresponding to FIG. 10.

Referring to FIG. 12, a chip pad CPD may be disposed on a pad PD. A flexible circuit board FPCB may be disposed on the chip pad CPD. The chip pad CPD may be disposed on the lower surface of the flexible circuit board FPCB.

An anisotropic conductive film ACF may be disposed between the substrate SUB and the flexible circuit board FPCB. The anisotropic conductive film ACF may include a resin layer RIN, and a plurality of conductive balls CB disposed in the resin layer RIN.

Some conductive balls CB among the conductive balls CB may be disposed between the pad PD and the chip pad CPD. Each of the conductive balls CB may have a first thickness TH1 in the third direction DR3. When the conductive balls CB are not deformed, the first thickness TH1 may be defined as a thickness of each of the conductive balls CB.

Hereinafter, the conductive balls CB referred to in describing FIGS. 12 and 13 indicate the conductive balls CB disposed between the pad PD and the chip pad CPD.

In an initial operation of an attaching process, an interval of the pad PD and the chip pad CPD may be defined as a first interval GP1. The first interval GP1 may be the same as the first thickness TH1 of each of the conductive balls CB. The conductive balls CB illustrated in FIG. 12 are in a state before being contracted, and an interval, between the pad PD and the chip pad CPD, before the conductive balls CB are contracted may be the first interval GP1.

Referring to FIGS. 11 and 12, a thickness of the insulating layer INS, and a thickness of each of the conductive balls CB may be the same as the first thickness TH1. Accordingly, an interval between a first electrode E1-1 and a second electrode E1-2 and an interval between the pad PD and the chip pad CPD may be the same as the first interval GP1. The insulating layer INS may have the same modulus as each of the conductive balls CB.

Referring to FIG. 13, the flexible circuit board FPCB may be pressed toward the substrate SUB. A predetermined pressure PS may be applied to the chip pad CPD so that the chip pad CPD may be pressed toward the pad PD. In order that the interval between the pad PD and the chip pad CPD is reduced from the first interval GP1 to a second interval GP2, the flexible circuit board FPCB may be pressed toward the substrate SUB.

When the flexible circuit board FPCB is pressed toward the substrate SUB, each of the conductive balls CB may be deformed from the first thickness TH1 to the second thickness TH2. The second thickness TH2 may be the same as the second interval GP2.

By the pressing process, the conductive balls CB may be contracted and be schematically deformed to an ellipsoidal form. Accordingly, between the pad PD and the chip pad CPD, a contact area of the conductive balls CB and the pad PD may increase, and thus a contact area of the conductive balls CB and the chip pad CPD may increase. The conductive balls CB may electrically connect the pad PD and the chip pad CPD. This process may be defined as a bonding process.

Referring to FIGS. 12 and 13, when the contact area of the conductive balls CB and the pad PD and the contact area of the conductive balls CB and the chip pad CPD increase, electrical connection characteristics of the pad PD and the chip pad CPD may be improved. When the contact area of the conductive balls CB and the pad PD and the contact area of the conductive balls CB and the chip pad CPD decrease, the electrical connection characteristics may deteriorate.

When the conductive balls CB is contracted to equal to or less than a predetermined thickness so that the contact area of the conductive balls CB and the pad PD and the contact area of the conductive balls CB and the chip pad CPD increase, an electrical connection state may be classified as a normal state. The thickness of the conductive balls CB may be substantially defined as the interval between the pad PD and the chip pad CPD. Accordingly, when the interval between the pad PD and the chip pad CPD is measured, whether or not the conductive balls CB are contracted may be confirmed.

When a plurality of display panels DP are manufactured, after the bonding process, one arbitrary display panel DP may be selected as a sample so as to measure the interval between the pad PD and the chip pad CPD. A portion of the pad PD and the chip pad CPD may be partially cut from the selected display panel DP. Thereafter, the interval between the pad PD and the chip pad CPD may be measured by measuring the cut portion with a measurement device.

The interval between the pad PD and the chip pad CPD may be measured in the cut display panel DP. The interval between the pad PD and the chip pad CPD of each of the rest of the display panels DP may be predicted from the interval between the pad PD and the chip pad CPD of the display panel DP cut as the sample.

However, in this case, one display panel DP must be damaged. In addition, the interval between the pad PD and the chip pad CPD of each of the rest of the display panels DP is a predicted value as a value of the cut display panel DP, and may not be a really measured value.

In an embodiment of the invention, the interval between the pad PD and the chip pad CPD may be measured in each of all display panels DP without cutting the display panel DP. This configuration will be described in detail later.

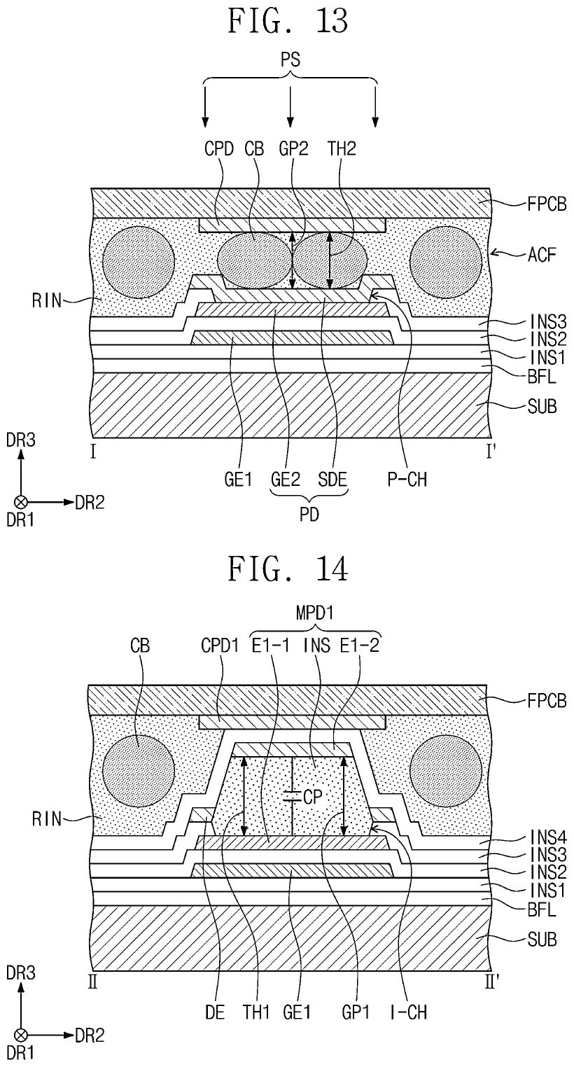

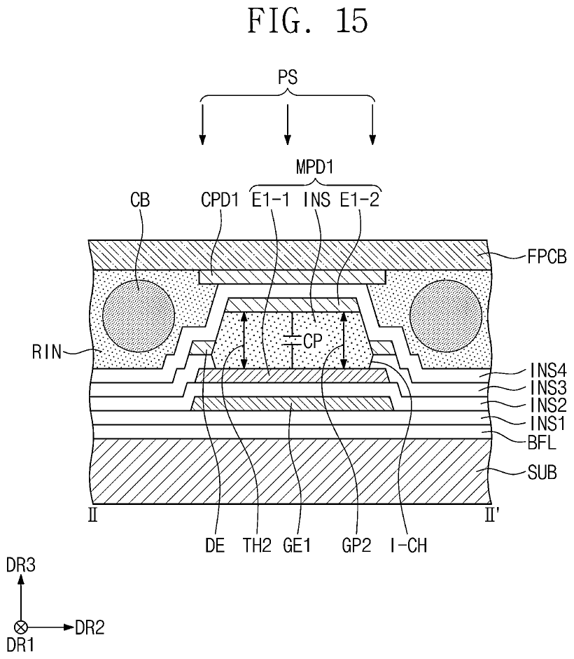

FIGS. 14 and 15 are diagrams illustrating a state of the insulating layer illustrated in FIG. 11, in a bonding process of a pad and a chip pad.

FIGS. 14 and 15 exemplarily illustrate a cross-section corresponding to FIG. 11, and FIG. 14 may correspond to FIG. 12, and FIG. 15 may correspond to FIG. 13.

Referring to FIG. 14, a first chip pad CPD1 may be disposed on a first measurement pad MPD1. The first chip pad CPD1 may be disposed on a fourth insulating layer INS4. A flexible circuit board FPCB may be disposed on the first chip pad CPD1. The first chip pad CPD1 may be disposed on the lower surface of the flexible circuit board FPCB. The first chip pad CPD1 may be separated from surrounding conductors, and thus may be defined as an “island type”.

An anisotropic conductive film ACF may be disposed between a substrate SUB and the flexible circuit board FPCB. However, due to a thickness of the insulating layer INS, conductive balls CB may not be disposed between the first measurement pad MPD1 and the first chip pad CPD1. For example, a space in which the conductive balls CB are disposed between the pad PD and the chip pad CPD is supplied in FIGS. 12 and 13, but the space may not be supplied in FIG. 14 due to the insulating layer INS.

Accordingly, the conductive balls CB may not be disposed between the first measurement pad MPD1 and the first chip pad CPD1. The conductive balls CB may be disposed around the first measurement pad MPD1 and the first chip pad CPD1. As described above, the insulating layer INS and the conductive balls CB may each have the same thickness as the first thickness TH1. In addition, an interval between the first electrode E1-1 and the second electrode E1-2 and an interval between the pad PD and the chip pad CPD may be the same as the first interval GP1.

Referring to FIG. 15, the flexible circuit board FPCB may be pressed toward the substrate SUB. A predetermined pressure PS may be applied to the first chip pad CPD1 so that the first chip pad CPD1 may be pressed toward the first measurement pad MPD1. In order that an interval between the first measurement pad MPD1 and the first chip pad CPD1 is contracted from the first interval GP1 to the second interval GP2, the flexible circuit board FPCB may be pressed toward the substrate SUB.

When the flexible circuit board FPCB is pressed toward the substrate SUB, the insulating layer INS may be deformed from the first thickness TH1 to the second thickness TH2. As described above, the insulating layer INS may have the same modulus as each of the conductive balls CB, and thus a contraction amount of the insulating layer INS may be same as a contraction amount of each of the conductive balls CB. Accordingly, in a bonding process, the insulating layer INS may be contracted to the same thickness as the conductive balls CB.

When the thickness of the insulating layer INS is reduced, the interval between the first electrode E1-1 and the second electrode E1-2 may be reduced from the first interval GP1 to the second interval GP2. The interval between the first electrode E1-1 and the second electrode E1-2 may be changed, and thus a capacitance of the capacitor CP may be changed. The interval between the first electrode E1-1 and the second electrode E1-2 may be reduced, and thus the capacitance of the capacitor CP may increase.

An amount of change in the capacitance may be generally defined as the following equation.

$$Δ C = ε \frac{S}{Δ d} \qquad [ Mathematical equation 1 ]$$

C may be a capacitance, S may be an area of conductors, d may be an interval between the conductors, and ε may be a dielectric constant. In Mathematical equation 1, an amount of change in d may be inversely proportional to an amount of change in C. Accordingly, the amount of change in d may be represented as the following Mathematical equation 2.

$$Δ d = ε \frac{S}{Δ C} \qquad [ Mathematical equation 2 ]$$

Since a manufacturer knows the first thickness TH1 before deforming the insulating layer INS, the first interval GP1 between the first electrode E1-1 and the second electrode E1-2 may be confirmed. A difference between an initial capacitance of the capacitor CP in FIG. 14 and a changed capacitance of the capacitor CP in FIG. 15 may be the amount of change in C. In addition, a difference between the first interval GP1 and the second interval GP2 may be the amount of change in d.

When the difference between the initial capacitance of the capacitor CP and the changed capacitance of the capacitor CP is measured, the second interval GP2, which is the same value as the second thickness TH2, may be measured. For example, since the difference between the initial capacitance of the capacitor CP and the changed capacitance of the capacitor CP is inversely proportional to the difference between the first interval GP1 and the second interval GP2, the second interval GP2 may be calculated according to an amount of change of the capacitor CP.

Since the conductive balls CB and the insulating layer INS are identically contracted, the second interval GP2 may be defined as an interval between the pad PD and the chip pad CPD. That is, the interval between the pad PD and the chip pad CPD may be measured according to the amount of change of the capacitor CP.

A change in the capacitance of the capacitor CP may be measured using the second measurement pad MPD2 and the third measurement pad MPD3 described earlier, and this configuration will be described in detail later.

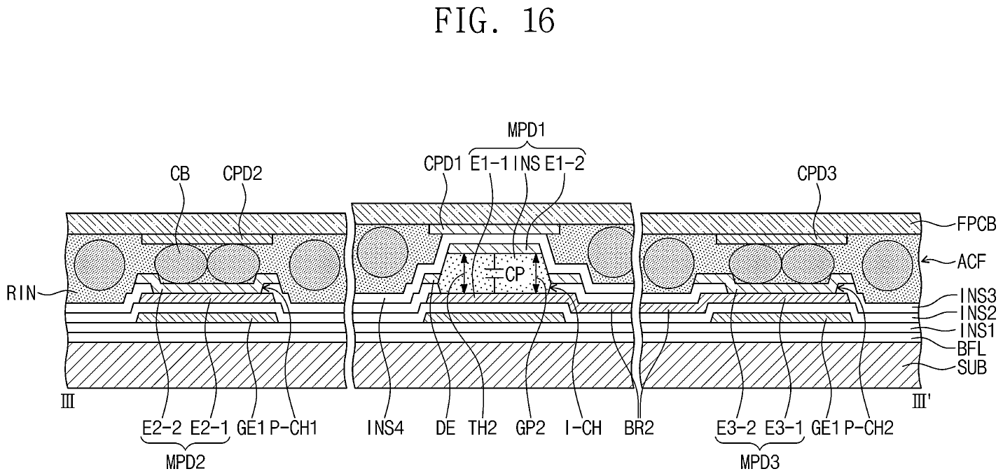

FIG. 16 is a cross-sectional view taken along line III-III′ illustrated in FIG. 9.

Referring to FIGS. 9 and 16, a second chip pad CPD2 may be disposed on a second measurement pad MPD2, and a third chip pad CPD3 may be disposed on a third measurement pad MPD3. A flexible circuit board FPCB may be disposed on the second chip pad CPD2 and the third chip pad CPD3.

The second measurement pad MPD2 may include a first electrode E2-1 and a second electrode E2-2 disposed on the first electrode E2-1. The first electrode E2-1 may be disposed on a second insulating layer INS2, and a third insulating layer INS3 may be disposed on the first electrode E2-1 and the second insulating layer INS2. The second electrode E2-2 may be disposed on the third insulating layer INS3. A first contact hole P-CH1 may be defined in the third insulating layer INS3, and the second electrode E2-2 may be connected to the first electrode E2-1 through the first contact hole P-CH1.

The third measurement pad MPD3 may include a first electrode E3-1 and a second electrode E3-2 disposed on the first electrode E3-1. The first electrode E3-1 may be disposed on the second insulating layer INS2, and the third insulating layer INS3 may be disposed on the first electrode E3-1 and the second insulating layer INS2. The second electrode E3-2 may be disposed on the third insulating layer INS3. A second contact hole P-CH2 may be defined in the third insulating layer INS3, and the second electrode E3-2 may be connected to the first electrode E3-1 through the second contact hole P-CH2.

A cross-sectional configuration of the second measurement pad MPD2 and the third measurement pad MPD3 may be substantially the same as a configuration of the pad PD described above. Accordingly, the first electrodes E2-1 and E3-1 may be formed by being simultaneously patterned with the same material as those of a second gate electrode GE2 and a first electrode E1-1. In addition, the second electrodes E2-2 and E3-2 may be formed by being simultaneously patterned with the same material as those of a source-drain electrode SDE and a first electrode E2-1.

The second measurement pad MPD2 may be electrically connected to the second chip pad CPD2. For example, conductive balls CB may be disposed between the second measurement pad MPD2 and the second chip pad CPD2, and the second measurement pad MPD2 and the second chip pad CPD2 may be electrically connected to each other by the conductive balls CB. The conductive balls CB may be disposed between the second electrode E2-2 and the second chip pad CPD2 so that the second electrode E2-2 and the second chip pad CPD2 may be electrically connected to each other.

The third measurement pad MPD3 may be electrically connected to the third chip pad CPD3. For example, conductive balls CB may be disposed between the third measurement pad MPD3 and the third chip pad CPD3, and the third measurement pad MPD3 and the third chip pad CPD3 may be electrically connected to each other by the conductive balls CB. The conductive balls CB may be disposed between the second electrode E3-2 and the third chip pad CPD3 so that the second electrode E3-2 and the third chip pad CPD3 may be electrically connected to each other.

A connection structure of the second measurement pad MPD2 and the second chip pad CPD2 and a connection structure of the third measurement pad MPD3 and the third chip pad CPD3 may be substantially the same as a connection structure of the pad PD and the chip pad CPD described above.

The first measurement pad MPD1 may be connected to the third measurement pad MPD3. As described above, the second bridge electrode BR2 may extend from the first electrode E1-1 of the first measurement pad MPD1 and the first electrode E3-1 of the third measurement pad MPD3. The first measurement pad MPD1 may be connected to the third measurement pad MPD3 by the second bridge electrode BR2.

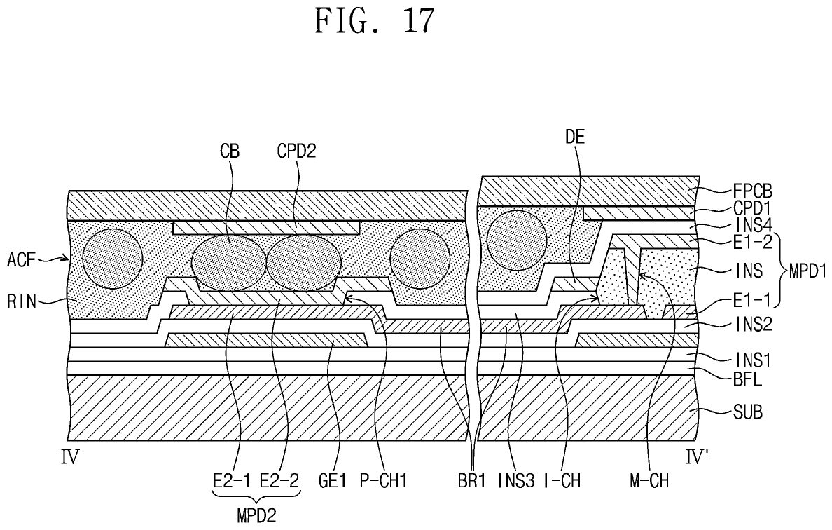

FIG. 17 is a cross-sectional view taken along line IV-IV′ illustrated in FIG. 9.

Referring to FIGS. 9 and 17, a first measurement pad MPD1 may be connected to a second measurement pad MPD2. As described above, a first bridge electrode BR1 may be formed by extending from a first electrode E2-1. The first bridge electrode BR1 may extend under the insulating layer INS.

When seen on a plane, one side of the first bridge electrode BR1 may overlap a second electrode E1-2. The second electrode E1-2 may be connected to the first bridge electrode BR1 through a contact hole M-CH defined in the second insulating layer INS2. The first measurement pad MPD1 may be connected to the second measurement pad MPD2 by the first bridge electrode BR1.

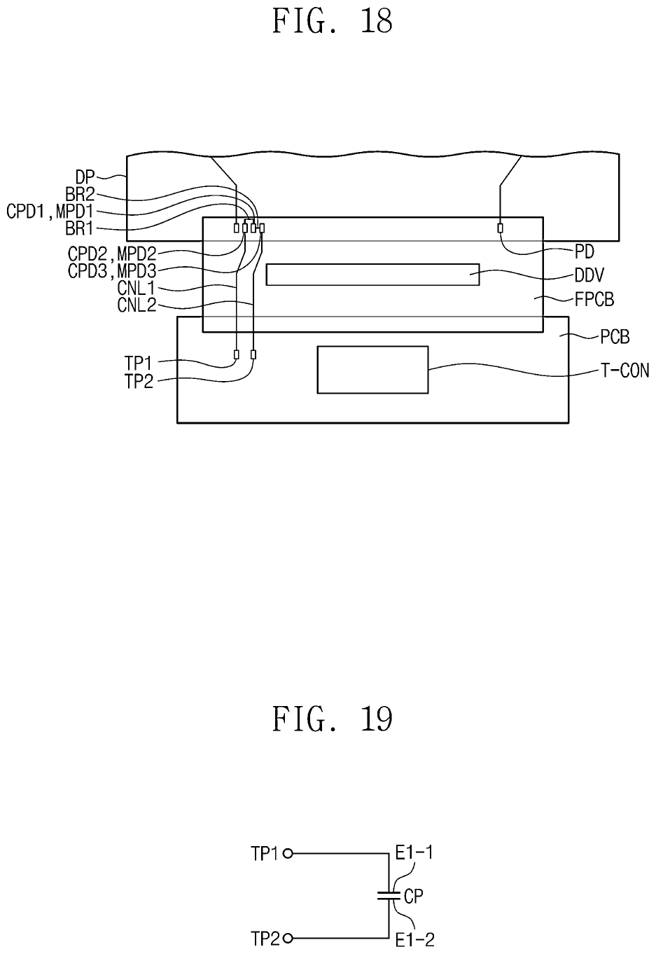

FIG. 18 is a diagram illustrating a state in which first to third measurement pads illustrated in FIG. 9 and first and second measurement terminals disposed on a printed circuit board are connected. FIG. 19 is a diagram illustrating a state in which a capacitor of the first measurement pad and the first and second measurement terminals illustrated in FIG. 18 are connected.

Exemplarily, drawing symbols for a first measurement pad MPD1 and a first chip pad CPD1, drawing symbols for a second measurement pad MPD2 and a second chip pad CPD2, and drawing symbols for a third measurement pad MPD3 and a third chip pad CPD3 which overlap each other in a plan view are illustrated together. In addition, FIG. 18 illustrates a portion of a display panel DP connected to a flexible circuit board FPCB, and a plan view of a printed circuit board PCB.

Referring to FIGS. 9, 16, 17, and 18, a first measurement terminal TP1 and a second measurement terminal TP2 may be disposed on the printed circuit board PCB connected to the flexible circuit board FPCB.

The first measurement pad MPD1 may be connected to the second measurement pad MPD2 through a first bridge electrode BR1, and the second chip pad CPD2 connected to the second measurement pad MPD2 may be connected to the first measurement terminal TP1 through a first connection line CNL1. The first connection line CNL1 may extend from the display panel DP to the flexible circuit board FPCB and the printed circuit board PCB.

The first measurement pad MPD1 may be connected to the third measurement pad MPD3 through a second bridge electrode BR2, and the third chip pad CPD3 connected to the third measurement pad MPD3 may be connected to the second measurement terminal TP2 through a second connection line CNL2. The second connection line CNL2 may extend from the display panel DP to the flexible circuit board FPCB and the printed circuit board PCB.

Referring to FIGS. 18 and 19, a capacitor CP may be formed by a first electrode E1-1 and a second electrode E1-2 of the first measurement pad MPD1. According to the structure described above, the second electrode E1-2 may be connected to the first measurement terminal TP1 through the first bridge electrode BR1, the second measurement pad MPD2, the second chip pad CPD2, and the first connection line CNL1. According to the structure described above, the first electrode E1-1 may be connected to the second measurement terminal TP2 through the second bridge electrode BR2, the third measurement pad MPD3, the third chip pad CPD3, and the second connection line CNL2.

A capacitance of the capacitor CP may be measured by getting a measurement device for measuring the capacitance in contact with the first measurement terminal TP1 and the second measurement terminal TP2. Accordingly, a change in the capacitance of the capacitor CP may be measured in a bonding process described in FIGS. 12 to 15.

The change in the capacitance of the capacitor CP may be measured, and a manufacturer may know a first interval GP1 between the first electrode E1-1 and the second electrode E1-2 from a first thickness TH1 of an insulating layer INS. According to Mathematical equation 2, an amount of change in an interval between the first electrode E1-1 and the second electrode E1-2 may be inversely proportional to an amount of the change in the capacitance of the capacitor CP. Accordingly, the second interval GP2 between the first electrode E1-1 and the second electrode E1-2 may be easily calculated from the measured amount of the change in the capacitance of the capacitor CP.

The interval between the pad PD and the chip pad CPD according to the bonding process may be defined as a bonding interval. Since the second interval GP2 is the interval between the pad PD and the chip pad CPD, the bonding interval between the pad PD and the chip pad CPD may be measured. Accordingly, according to an embodiment of the invention, the interval between the pad PD and the chip pad CPD may be easily measured without cutting the display panel DP. Electrical connection characteristics between the pad PD and the chip pad CPD may be more easily confirmed from the bonding interval.

According to an embodiment of the invention, when an amount of change in the interval between the first electrode E1-1 and the second electrode E1-2 is measured, a pressure of the bonding process may be measured through the following mathematical equation.

A bulk modulus may be defined as the following Mathematical equation 3.

$$B = \frac{Δ P}{Δ V / V} \qquad [ Mathematical equation 3 ]$$

B is a bulk modulus of a corresponding object, P is a pressure, and V is a volume.

According to Mathematical equation 3, the pressure may be defined as the following Mathematical equation 4.

$$Δ P = B \times Δ V / V \qquad [ Mathematical equation 4 ]$$

An amount of change in the volume of the corresponding object may substantially correspond to an amount of change in a thickness of the corresponding object.

Since a manufacturer knows the bulk modulus of the insulating layer INS, and the thickness of the insulating layer INS changes from a first thickness TH1 to a second thickness TH2 in the bonding process, the manufacturer may know the amount of change in the thickness of the insulating layer INS. The amount of change in the volume may correspond to the amount of change in the thickness, and the amount of change in the thickness may correspond to a difference value between the first interval GP1 and the second interval GP2. Accordingly, when the volume V is substituted with a distance d, the following Mathematical equation 5 may be calculated.

$$Δ P \approx B \times Δ d / d \qquad [ Mathematical equation 5 ]$$

Since d is an interval between the first electrode E1-1 and the second electrode E1-2, an amount of change in d may be the amount of change in the interval between the first electrode E1-1 and the second electrode E1-2 described above. According to an embodiment of the invention, since the amount of change in the interval between the first electrode E1-1 and the second electrode E1-2 is measured, the amount of change in the pressure in the bonding process may be easily measured. As illustrated in FIGS. 13 and 15, since a pressure PS is applied to the first connection portion CP1 and the chip pad CPD in the bonding process, a change in the pressure PS applied to the chip pad CPD may be easily measured.

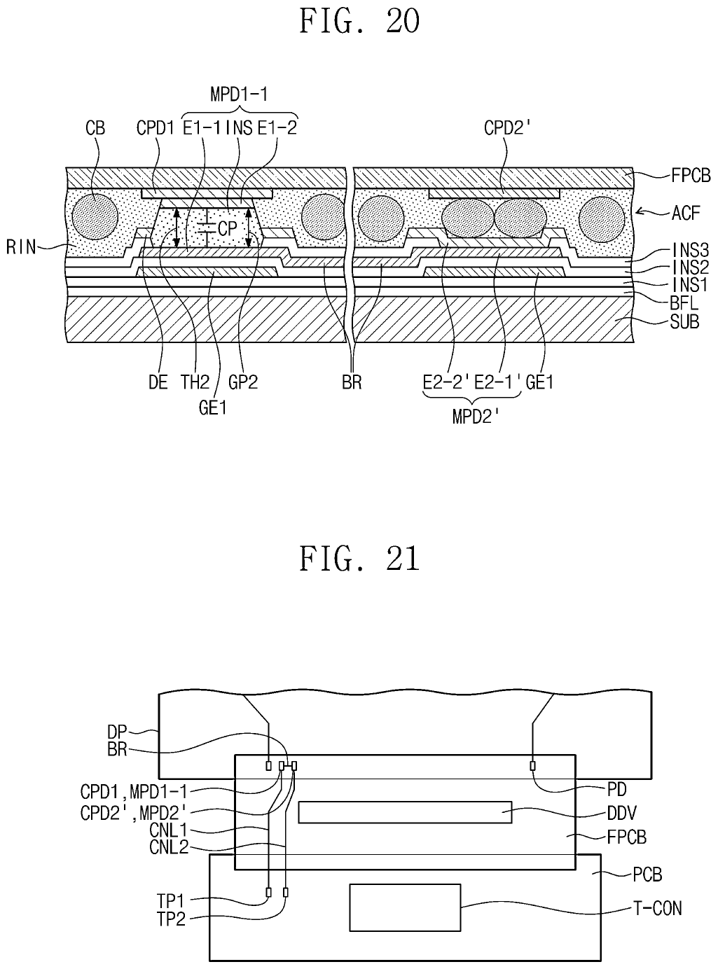

FIG. 20 is a diagram illustrating a configuration of a first measurement pad and a second measurement pad according to another embodiment of the invention. FIG. 21 is a diagram illustrating a status in which the first and second measurement pads illustrated in FIG. 20 and first and second terminals disposed on a printed circuit board are connected.

FIG. 20 illustrates a cross-section corresponding to FIG. 16, and FIG. 21 illustrates a plan view corresponding to FIG. 18.

Hereinafter, configurations illustrated in FIGS. 20 and 21 will be described focusing on differences from those illustrated in FIGS. 16 and 18.

Referring to FIG. 20, a first measurement pad MPD1-1 may be electrically connected to a first chip pad CPD1. For example, the first chip pad CPD1 may be disposed on the second electrode E1-2. The first chip pad CPD1 may be in contact with the second electrode E1-2 to be electrically connected to the second electrode E1-2. Unlike the configuration illustrated in FIG. 16, a fourth insulating layer INS4 may not be disposed on the second electrode E1-2. In addition, the second measurement pad MPD2 and the second chip pad CPD2 illustrated in FIG. 16 may not be used.

A second measurement pad MPD2′ may include a first electrode E2-1′ and a second electrode E2-2′, and a second chip pad CPD2′ may be disposed on the second measurement pad MPD2′. Conductive balls CB may be disposed between the second measurement pad MPD2′ and the second chip pad CPD2′. A flexible circuit board FPCB may be disposed on the first and second chip pads CPD1 and CPD2′. A configuration of the second measurement pad MPD2′ and the second chip pad CPD2′ may be substantially the same as a configuration of the third measurement pads MPD3 and the third chip pad CPD3 illustrated in FIG. 16.

The first measurement pad MPD1 may be connected to the second measurement pad MPD2′. A structure in which the first measurement pad MPD1 is connected to the second measurement pad MPD2′ may be substantially the same as the structure in which the first measurement pad MPD1 illustrated in FIG. 16 is connected to the third measurement pad MPD3. That is, the second measurement pad MPD2′ may be connected to the first electrode E1-1 by the bridge electrode BR (corresponding to the first bridge electrode BR1 illustrated in FIG. 16) extending from the first electrode E1-1.

Referring to FIGS. 20 and 21, the first measurement pad MPD1-1 may be connected to the first chip pad CPD1, and the first chip pad CPD1 may be connected to the first measurement terminal TP1 through the first connection line CNL1.

The first measurement pad MPD1-1 may be connected to the second measurement pad MPD2′ through the bridge electrode BR, and the second chip pad CPD2′ connected to the second measurement pad MPD2′ may be connected to the second measurement terminal TP2 through the second connection line CNL2.

The second electrode E1-2 of the first measurement pad MPD1-1 may be connected to the first measurement terminal TP1 through the first chip pad CPD1 and the first connection line CNL1. The first electrode E1-1 of the first measurement pad MPD1-1 may be connected to the second measurement terminal TP2 through the bridge electrode BR, the second measurement pad MPD2′, the second chip pad CPD2′, and the second connection line CNL2. A capacitance of the capacitor CP may be measured through the first and second measurement terminals TP1 and TP2.

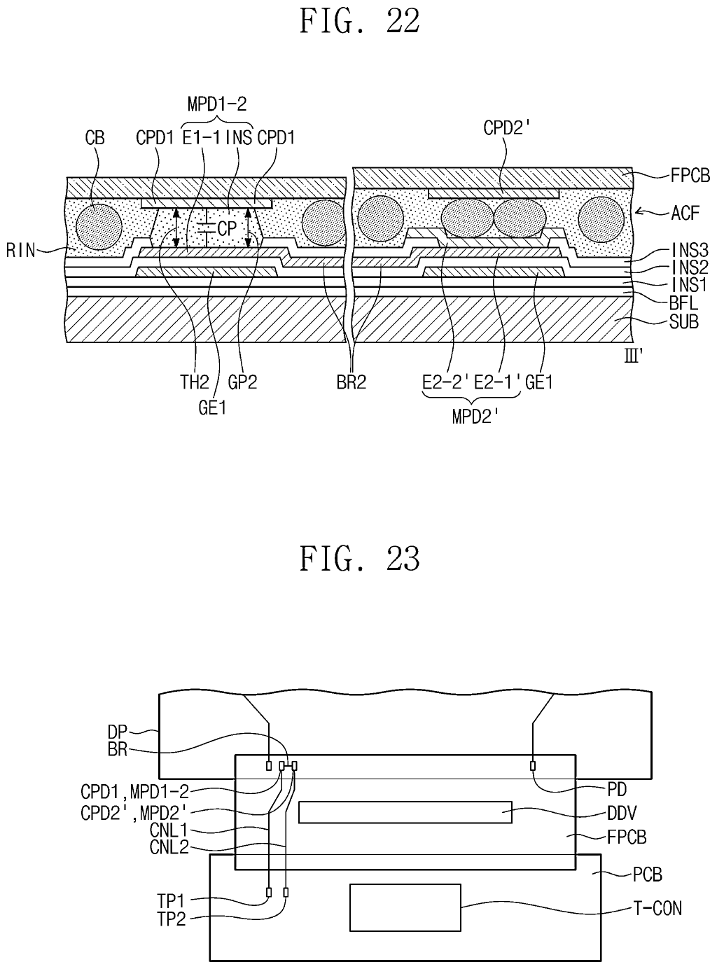

FIG. 22 is a diagram illustrating a configuration of a first measurement pad and a second measurement pad according to still another embodiment of the invention. FIG. 23 is a diagram illustrating a status in which the first and second measurement pads illustrated in FIG. 22 and first and second measurement terminals disposed on a printed circuit board are connected.

FIG. 22 illustrates a cross-section corresponding to FIG. 20, and FIG. 23 illustrates a plan view corresponding to FIG. 21.

Hereinafter, configurations illustrated in FIGS. 22 and 23 will be described focusing on differences from those illustrated in FIGS. 20 and 21.

Referring to FIG. 22, a first measurement pad MPD1-2 may include a first electrode E1-1 and an insulating layer INS. A first chip pad CPD1 may be disposed on the insulating layer INS. Unlike the first measurement pad MPD1-1 illustrated in FIG. 20, the first measurement pad MPD1-2 may not include the second electrode E1-2. Configurations illustrated in FIG. 22 may be substantially the same as those illustrated in FIG. 20. A capacitor CP may be formed by the first electrode E1-1 and the first chip pad CPD1.

Referring to FIGS. 22 and 23, the first chip pad CPD1 disposed on the first measurement pad MPD1-2 may be connected to the first measurement terminal TP1 through the first connection line CNL1. The first electrode E1-1 of the first measurement pad MPD1-2 may be connected to the second measurement terminal TP2 through the bridge electrode BR, the second measurement pad MPD2′, the second chip pad CPD2′, and the second connection line CNL2. A capacitance of the capacitor CP may be measured through the first and second measurement terminals TP1 and TP2.

According to an embodiment of the invention, a first measurement pad may include a first electrode, a second electrode on the first electrode, and an insulating layer between the first and second electrodes, and the first electrode may be connected to a second measurement pad, and the second electrode may be connected to a third measurement pad.

A change in a capacitance formed by the first and second electrodes may be measured through a first measurement terminal connected to the second measurement pad and a second measurement terminal connected to the third measurement pad, and thus bonding intervals between pads and chip pads may be measured. Electrical connection characteristics between the pads and the chip pads may be more easily confirmed from the bonding interval.

In the above, description has been made with reference to preferred embodiments of the invention, but those skilled in the art or those of ordinary skill in the relevant technical field may understand that various modifications and changes may be made to the invention within the scope not departing from the spirit and the technology scope of the invention described in the claims to be described later. In addition, embodiments disclosed in the invention are not intended to limit the technical idea of the invention, and all technical ideas within the scope of the following patent claims and equivalents should be construed as being included in the scope of the invention.

What is claimed is:

1. A display device comprising:
a substrate;
a pixel disposed on the substrate; and
a first measurement pad disposed on the substrate,
wherein the first measurement pad includes:
a first electrode disposed on the substrate;
a second electrode disposed on the first electrode, and electrically separated from the first electrode; and
an insulating layer disposed between the first electrode and the second electrode.

2. The display device of claim 1, wherein the first measurement pad is not connected to the pixel.

3. The display device of claim 1, wherein the insulating layer comprises an organic insulating layer.

4. The display device of claim 1, wherein the insulating layer comprises polymer.

5. The display device of claim 1, further comprising:
a pad electrically connected to the pixel;
a chip pad disposed on the pad; and
a conductive ball disposed between the pad and the chip pad.

6. The display device of claim 5, wherein the insulating layer has a same modulus as the conductive ball.

7. The display device of claim 5, wherein, in a direction perpendicular to an upper surface of the substrate, the insulating layer has a same thickness as the conductive ball, and
an interval between the first electrode and the second electrode is the same as an interval between the pad and the chip pad.

8. The display device of claim 7, wherein the insulating layer has a thickness of about 2 micrometers (μm) to about 4 μm.

9. The display device of claim 1, wherein a capacitance formed by the first electrode and the second electrode is about 0.02 picofarads (pF) to about 0.20 pF.

10. The display device of claim 1, further comprising an intermediate insulating layer disposed on the second electrode.

11. The display device of claim 10, further comprising:
a first chip pad disposed on the intermediate insulating layer; and
a flexible circuit board disposed on the first chip pad.

12. The display device of claim 11, wherein the first chip pad is separated from a surrounding conductor, and is defined as an island type.

13. The display device of claim 11, further comprising:
a second measurement pad electrically connected to the second electrode;
a second chip pad disposed on the second measurement pad and electrically connected to the second measurement pad;
a third measurement pad electrically connected to the first electrode; and
a third chip pad disposed on the third measurement pad and electrically connected to the third measurement pad.

14. The display device of claim 13, further comprising a plurality of conductive balls disposed between the second measurement pad and the second chip pad and between the third measurement pad and the third chip pad,
wherein the flexible circuit board is disposed on the second and third chip pads.

15. The display device of claim 13, further comprising:
a first measurement terminal electrically connected to the second chip pad; and
a second measurement terminal electrically connected to the third chip pad.

16. The display device of claim 15, further comprising a printed circuit board connected to the flexible circuit board,
wherein the first and second measurement terminals are disposed on the printed circuit board.

17. The display device of claim 1, further comprising:
a first chip pad disposed on the second electrode;
a second measurement pad electrically connected to the first electrode;
a second chip pad disposed on the second measurement pad;
a conductive ball disposed between the second measurement pad and the second chip pad; and
a flexible circuit board disposed on the first and second chip pads.

18. The display device of claim 17, further comprising:
a printed circuit board connected to the flexible circuit board;
a first measurement terminal disposed on the printed circuit board to be electrically connected to the first chip pad; and
a second measurement terminal disposed on the printed circuit board to be electrically connected to the second chip pad.

19. A display device comprising:
a substrate;
a pixel disposed on the substrate;
a measurement pad disposed on the substrate; and
a chip pad disposed on the measurement pad,
wherein the measurement pad includes:
an electrode disposed on the substrate; and
an insulating layer disposed on the electrode, and
wherein the chip pad is disposed on the insulating layer.

20. A display device comprising:
a substrate;
a plurality of pixels disposed on the substrate;
a plurality of pads disposed on the substrate to be connected to the pixels;
a measurement pad not connected to the pixels, and including a first electrode disposed on the substrate, a second electrode disposed on the first electrode, and an insulating layer disposed between the first electrode and the second electrode;
an intermediate insulating layer disposed on the second electrode; and
a chip pad disposed on the intermediate insulating layer,
wherein the chip pad is separated from a surrounding conductor to be defined as an island type.
